(19) United States
(12) Patent Application Publication
(10) Pub. No.: US 2026/0204516 A1
(43) Pub. Date: Jul. 16, 2026

(54) PLASMA PROCESSING APPARATUS

(71) Applicant: Tokyo Electron Limited, Tokyo (JP)

(72) Inventors: Ikko TANAKA, Miyagi (JP); Yuki IIJIMA, Miyagi (JP)

(73) Assignee: Tokyo Electron Limited, Tokyo (JP)

(21) Appl. No.: 19/557,293

(22) Filed: Mar. 5, 2026

Related U.S. Application Data
(63) Continuation of application No. PCT/JP2024/028749, filed on Aug. 9, 2024.

(30) Foreign Application Priority Data
Sep. 15, 2023 (JP) 2023-149899

(51) Int. Cl. H01J 37/32

(52) U.S. Cl. CPC H01J 37/32146; H01J 37/32183; H01J 37/32981; H01J 2237/24585

(57) ABSTRACT

A plasma processing apparatus includes: a chamber; a substrate support including a lower electrode; an RF generator that generates a pulsed RF signal having a first power level in a first period in each cycle and having a second power level in a second period in each cycle in order to generate plasma in the chamber; a pulsed voltage generator that generates a pulsed voltage signal having a reference voltage level in the first period and having a sequence of a plurality of voltage pulses having a first voltage level in the second period; a microwave interferometer that monitors an electron density of plasma; and controller circuitry that controls the RF generator to adjust the first power level based on an electron density in the first period, and that controls the pulsed voltage generator to adjust the first voltage level based on an electron density in the second period.

### CROSS-REFERENCE TO RELATED APPLICATIONS

This application is a continuation of International Application No. PCT/JP2024/028749, filed on Aug. 9, 2024 which claims the benefit of priority of the prior Japanese Patent Application No. 2023-149899, filed on Sep. 15, 2023, the entire contents of each are incorporated herein by reference.

### FIELD

The present disclosure relates to a plasma processing apparatus.

### BACKGROUND

An etching apparatus disclosed in JP 2004-128236 A includes a substrate electrode and a source electrode. The substrate electrode is used to apply high-frequency power to a substrate on which an etching process is conducted. The source electrode is used to generate plasma supplied onto the substrate electrode. Then, an electron density control unit and an ion energy control unit are provided. The electron density control unit controls high-frequency power applied to the source electrode so that the electron density in the plasma supplied onto the substrate electrode reaches a predetermined set value. The ion energy control unit controls high-frequency power applied to the substrate electrode so that ion energy in the plasma supplied onto the substrate electrode has a predetermined set value.

### SUMMARY

(1) According to an aspect of the present disclosure, there is provided a plasma processing apparatus including: a chamber; a substrate support disposed in the chamber and including a lower electrode; an RF generator that generates a pulsed RF signal in order to generate plasma in the chamber, the pulsed RF signal having a first power level in a first period in each cycle and having a second power level smaller than the first power level in a second period in each cycle; a pulsed voltage generator that is electrically connected to the lower electrode and that generates a pulsed voltage signal, the pulsed voltage signal having a reference voltage level in the first period and having a sequence of a plurality of voltage pulses having a first voltage level in the second period, the first voltage level having an absolute value larger than an absolute value of the reference voltage level; a microwave interferometer that monitors an electron density of plasma in the chamber; and controller circuitry configured to: control the RF generator to adjust the first power level based on an electron density of plasma monitored in the first period, and control the pulsed voltage generator to adjust the first voltage level based on an electron density of plasma monitored in the second period.

(2) The plasma processing apparatus according to (1), wherein, when the electron density in the first period is less than a target value, the controller circuitry is configured to control the RF generator to increase the first power level.

(3) The plasma processing apparatus according to (1), wherein, when the electron density in the first period exceeds a target value, the controller circuitry is configured to control the RF generator to decrease the first power level.

(4) The plasma processing apparatus according to (1), wherein, when the electron density in the second period is less than a target value, the controller circuitry is configured to control the pulsed voltage generator to increase an absolute value of the first voltage level.

(5) The plasma processing apparatus according to (1), wherein, when the electron density in the second period exceeds a target value, the controller circuitry is configured to control the pulsed voltage generator to decrease an absolute value of the first voltage level.

(6) The plasma processing apparatus according to (1), wherein the pulsed voltage signal has a phase offset with respect to the pulsed RF signal.

(7) The plasma processing apparatus according to (1), wherein the first period has a duty ratio in a range of 10 to 60% of a repetition period of each cycle.

(8) The plasma processing apparatus according to (1), wherein the pulsed RF signal has a repetition frequency in a range of 0.1 to 50 kHz.

(9) The plasma processing apparatus according to (1), wherein the microwave interferometer includes a pair of electromagnetic horns attached to a side wall of the chamber so as to face each other, and measures the electron density based on a phase difference between a transmitted microwave and a received microwave.

(10) The plasma processing apparatus according to (9), wherein the controller circuitry is configured to control the RF generator to increase the first power level when the electron density in the first period is less than a target value, and controls the pulsed voltage generator to increase an absolute value of the first voltage level when the electron density in the second period is less than the target value.

(11) The plasma processing apparatus according to (1), wherein the controller circuitry controls the RF generator to decrease the first power level when the electron density in the first period exceeds a target value, and controls the pulsed voltage generator to decrease an absolute value of the first voltage level when the electron density in the second period exceeds the target value.

(12) A plasma processing apparatus comprising: a chamber; a substrate support disposed in the chamber and including a lower electrode; an RF generator that generates a pulsed RF signal in order to generate plasma in the chamber, the pulsed RF signal having a first power level in a first period in each cycle and having a second power level smaller than the first power level in a second period in each cycle; a pulsed voltage generator that is electrically connected to the lower electrode and that generates a pulsed voltage signal, the pulsed voltage signal having a reference voltage level in a delay period in the first period, having a sequence of a plurality of voltage pulses having a first voltage level in the first period excluding the delay period, and having the reference voltage level in the second period, the first voltage level having an absolute value larger than an absolute value of the reference voltage level, the delay period falling within a range of 2 to 7% of a total period in each cycle; a microwave interferometer that monitors an electron density of plasma in the chamber; and controller circuitry configured to control the RF generator to adjust at least one of the first power level and the delay period based on an electron density of plasma monitored in the delay period.

(13) The plasma processing apparatus according to (12), wherein, when the electron density is less than a target value, the controller circuitry is configured to adjust the RF generator increase the first power level or extend the delay period.

(14) The plasma processing apparatus according to (12), wherein, when the electron density exceeds a target value, the controller circuitry is configured to control the RF generator to decrease the first power level or shorten the delay period.

(15) The plasma processing apparatus according to (12), wherein the first period has a duty ratio in a range of 10 to 60% of a total period of each cycle.

(16) The plasma processing apparatus according to (12), wherein the pulsed RF signal has a repetition frequency in a range of 0.1 to 50 kHz.

(17) The plasma processing apparatus according to (12), wherein a sequence of the plurality of voltage pulses in the first period excluding the delay period has a pulse frequency in a range of 100 kHz to 1 MHz.

(18) A plasma control method comprising: generating plasma in a chamber by supplying a pulsed RF signal to a substrate support disposed in the chamber and including a lower electrode, the pulsed RF signal having a first power level in a first period in each cycle and having a second power level smaller than the first power level in a second period in each cycle; supplying a pulsed voltage signal to the lower electrode, the pulsed voltage signal having a reference voltage level in a delay period in the first period, having a sequence of a plurality of voltage pulses having a first voltage level in the first period excluding the delay period, and having the reference voltage level in the second period, the first voltage level having an absolute value larger than an absolute value of the reference voltage level, the delay period falling within a range of 2 to 7% of a total period of each cycle; measuring an electron density of the plasma; and adjusting at least one of the first power level and the delay period based on the electron density measured in the delay period.

(19) The plasma control method according to (18), wherein the adjusting includes increasing the first power level or extending the delay period when the electron density is less than a target value.

(20) The plasma control method according to 18, wherein the adjusting includes decreasing the first power level or shortening the delay period when the electron density exceeds a target value.

### BRIEF DESCRIPTION OF DRAWINGS

FIG. 1 illustrates an example of a plasma processing system in a first embodiment of the present disclosure;

FIG. 2 is a schematic cross-sectional view illustrating an example of a configuration of a plasma processing apparatus in the first embodiment;

FIG. 3 is a timing chart illustrating an example of supply timing of RF power and a DC pulse and a change in electron density in the first embodiment;

FIG. 4 is a timing chart illustrating an example of the supply timing of the RF power and the DC pulse in the first embodiment;

FIG. 5 is a timing chart obtained by enlarging a part of the timing chart of FIG. 4;

FIG. 6 is a timing chart illustrating an example of the supply timing of RF power and a DC pulse and the change in electron density in the first embodiment;

FIG. 7 illustrates an example of a change in electron density near an offset period in a case where an amount of deposition is at an appropriate level;

FIG. 8 schematically illustrates deposition and etching in the case where an amount of deposition is at an appropriate level;

FIG. 9 illustrates an example of a change in electron density near the offset period in a case where an amount of deposition is insufficient;

FIG. 10 schematically illustrates deposition and etching in the case where an amount of deposition is insufficient;

FIG. 11 illustrates an example of a change in electron density near the offset period in a case where an amount of deposition is excessive;

FIG. 12 schematically illustrates deposition and etching in the case where an amount of deposition is excessive;

FIG. 13 illustrates an example of a method of adjusting electron density at the start timing of a period P1;

FIG. 14 illustrates an example of the method of adjusting electron density at the start timing of the period P1;

FIG. 15 is a flowchart illustrating an example of plasma control processing according to the first embodiment;

FIG. 16 illustrates an example of a timing chart for one cycle of a synchro pulse;

FIG. 17 illustrates an example of the timing chart for one cycle of an offset pulse;

FIG. 18 illustrates an example of the timing chart for one cycle of an offset pulse;

FIG. 19 illustrates an example of the timing chart for one cycle of an offset pulse;

FIG. 20 is a graph illustrating an example of a change in electron density in a repetition period in a second embodiment; and

FIG. 21 is a flowchart illustrating an example of plasma control processing according to the second embodiment.

### DESCRIPTION OF EMBODIMENTS

Embodiments of a plasma processing apparatus to be disclosed will be described in detail below with reference to the drawings. Note that disclosed technology is not limited by the following embodiments.

The present disclosure provides a plasma processing apparatus capable of inhibiting a temporal change in a plasma condition.

In an etching process, a power level of an RF power source (source RF power) is set as one parameter for generating plasma among process conditions. If the etching process is conducted for a long time, however, the impedance of a chamber viewed from the side of the RF power source changes due to wear of a part in the chamber and a by-product (deposition) deposited onto the part. When power levels supplied from the RF power source have the same value, the electron density of generated plasma changes as the impedance of the chamber temporally changes. That is, a plasma condition temporally changes. Such a temporal change in a plasma condition causes a decrease in an etching rate and a change (process shift) in an etching shape. Thus, inhibition of the temporal change in a plasma condition is expected.

### First Embodiment

### Configuration of Plasma Processing System

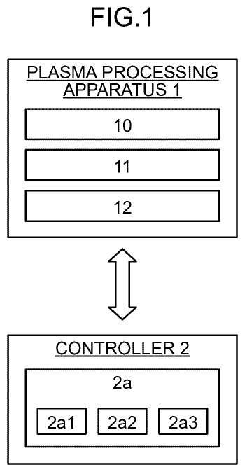

FIG. 1 illustrates an example of a plasma processing system in a first embodiment of the present disclosure. In the embodiment, the plasma processing system includes a plasma processing apparatus 1 and a controller 2. The plasma processing system is an example of a substrate processing system. The plasma processing apparatus 1 is an example of a substrate processing apparatus. The plasma processing apparatus 1 includes a plasma processing chamber 10, a substrate support unit 11, and a plasma generator 12. The plasma processing chamber 10 has plasma processing space. Furthermore, the plasma processing chamber 10 has at least one gas supply port and at least one gas discharge port. The gas supply port supplies at least one type of processing gas to the plasma processing space. The gas discharge port discharges gas from the plasma processing space. The gas supply port is connected to a gas supply unit 20 to be described later. The gas discharge port is connected to an exhaust system 40 to be described later. The substrate support unit 11 is disposed in the plasma processing space, and has a substrate support surface for supporting a substrate.

The plasma generator 12 generates plasma from at least one type of processing gas supplied into the plasma processing space. Examples of the plasma formed in the plasma processing space may include capacitively coupled plasma (CCP), inductively coupled plasma (ICP), electron-cyclotron-resonance (ECR) plasma, helicon wave plasma (HWP), and surface wave plasma (SWP). Furthermore, various types of plasma generators including an alternating current (AC) plasma generator and a direct current (DC) plasma generator may be used. In the embodiment, an AC signal (AC power) used in the AC plasma generator has a frequency in a range of 100 kHz to 10 GHz. Therefore, the AC signal includes a radio frequency (RF) signal and a microwave signal. In the embodiment, an RF signal has a frequency in a range of 100 kHz to 150 MHz.

The controller 2 processes a computer-executable instruction for causing the plasma processing apparatus 1 to execute various processes described in the present disclosure. The controller 2 can control various elements of the plasma processing apparatus 1 to execute the various processes here. In the embodiment, the plasma processing apparatus 1 may include a part or all of the controller 2. The controller 2 may include a processor 2a1, a storage 2a2, and a communication interface 2a3. The controller 2 may be implemented by, for example, a computer 2a. The processor 2a1 can read a program from the storage 2a2, and perform various control operations by executing the read program. The program may be preliminarily stored in the storage 2a2, or may be acquired via a medium when necessary. The storage 2a2 stores the acquired program. The processor 2a1 reads the program from the storage 2a2, and executes the program. Various storage media that can be read by the computer 2a may be used as the medium. A communication line connected to the communication interface 2a3 may be used as the medium. The processor 2a1 may be a central processing unit (CPU). The storage 2a2 may include a random access memory RAM, a read only memory (ROM), a Hard Disk Drive (HDD), a solid state drive (SSD), or a combination thereof. The communication interface 2a3 may communicate with the plasma processing apparatus 1 via a communication line such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium, such as a CD-ROM or DVD, and/or the memory of a FPGA or ASIC.

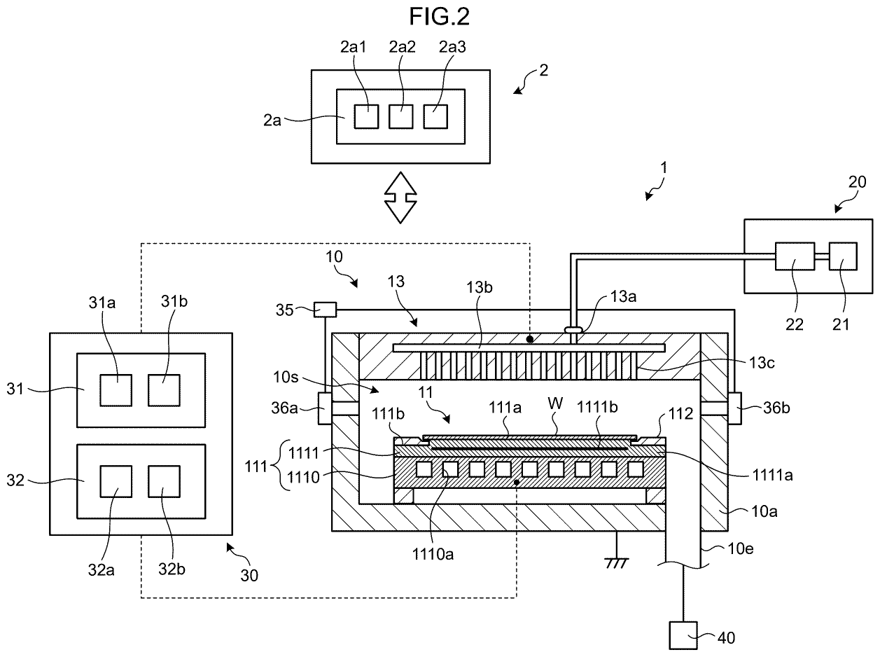

A configuration example of a capacitively coupled plasma processing apparatus serving as an example of the plasma processing apparatus 1 will be described below. FIG. 2 is a schematic cross-sectional view illustrating the example of the configuration of the plasma processing apparatus in the first embodiment.

The capacitively coupled plasma processing apparatus 1 includes the plasma processing chamber 10, the gas supply unit 20, a power source 30, a microwave interferometer 35, and the exhaust system 40. Furthermore, the plasma processing apparatus 1 includes the substrate support unit 11 and a gas introduction unit. The gas introduction unit introduces at least one type of processing gas into the plasma processing chamber 10. The gas introduction unit includes a shower head 13. The substrate support unit 11 is disposed in the plasma processing chamber 10. The shower head 13 is disposed above the substrate support unit 11. In the embodiment, the shower head 13 constitutes at least a part of a ceiling of the plasma processing chamber 10. The plasma processing chamber 10 has plasma processing space 10s specified by the shower head 13, a side wall 10a of the plasma processing chamber 10, and the substrate support unit 11. The plasma processing chamber 10 is grounded. The shower head 13 and the substrate support unit 11 are electrically insulated from a case of the plasma processing chamber 10.

The substrate support unit 11 includes a main body 111 and a ring assembly 112. The main body 111 has a central region 111a and an annular region 111b. The central region 111a supports a substrate W. The annular region 111b supports the ring assembly 112. Examples of the substrate W include a wafer. The annular region 111b of the main body 111 surrounds the central region 111a of the main body 111 in plan view. The substrate W is disposed on the central region 111a of the main body 111. The ring assembly 112 is disposed on the annular region 111b of the main body 111 so as to surround the substrate W on the central region 111a of the main body 111. Therefore, the central region 111a is also referred to as a substrate support surface for supporting the substrate W. The annular region 111b is also referred to as a ring support surface for supporting the ring assembly 112.

In the embodiment, the main body 111 includes a base 1110 and an electrostatic chuck 1111. The base 1110 includes a conductive member. The conductive member of the base 1110 can function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In the embodiment, the ceramic member 1111a also has the annular region 111b. Note that another member that surrounds the electrostatic chuck 1111, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 1111 and the annular insulating member. Furthermore, at least one RF/DC electrode coupled to an RF power source 31 and/or a DC power source 32 to be described later may be disposed in the ceramic member 1111a. In this case, at least one RF/DC electrode functions as a lower electrode. When a bias RF signal and/or a DC signal to be described later is supplied to at least one RF/DC electrode, the RF/DC electrode is also referred to as a bias electrode. Note that the conductive member of the base 1110 and at least one RF/DC electrode may function as a plurality of lower electrodes. Furthermore, the electrostatic electrode 1111b may function as a lower electrode. Therefore, the substrate support unit 11 includes at least one lower electrode.

The ring assembly 112 includes one or a plurality of annular members. In the embodiment, one or a plurality of annular members includes one or a plurality of edge rings and at least one cover ring. The edge rings are formed of conductive material or insulating material. The cover ring is formed of insulating material.

Furthermore, the substrate support unit 11 may include a temperature adjusting module that adjusts at least one of the electrostatic chuck 1111, the ring assembly 112, and the substrate to a target temperature. The temperature adjusting module may include a heater, a heat-transfer medium, a flow path 1110a, or a combination thereof. Heat-transfer fluid such as brine and gas flows through the flow path 1110a. In the embodiment, the flow path 1110a is formed in the base 1110, and one or a plurality of heaters is disposed in the ceramic member 1111a of the electrostatic chuck 1111. Furthermore, the substrate support unit 11 may include a heat-transfer gas supply unit that supplies heat-transfer gas to a gap between the back surface of the substrate W and the central region 111a.

The shower head 13 introduces at least one type of processing gas from the gas supply unit 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b to be introduced from the plurality of gas introduction ports 13c into the plasma processing space 10s. Furthermore, the shower head 13 includes at least one upper electrode. Note that, in addition to the shower head 13, the gas introduction unit may include one or a plurality of side gas injectors (SGI), which is attached to one or a plurality of openings formed in the side wall 10a.

The gas supply unit 20 may include at least one gas source 21 and at least one flow controller 22. In the embodiment, the gas supply unit 20 supplies at least one type of processing gas from a gas source 21 for the processing gas to the shower head 13 via a flow controller 22 for the processing gas. A flow controller 22 may include a mass flow controller or a pressure control flow controller. Moreover, the gas supply unit 20 may include at least one flow modulation device that modulates or pulses the flow volume of at least one type of processing gas.

The power source 30 includes the RF power source 31 coupled to the plasma processing chamber 10 via at least one impedance matching circuit. The RF power source 31 supplies at least one RF signal (RF power) to at least one lower electrode and/or at least one upper electrode. This causes plasma to be formed from at least one type of processing gas supplied to the plasma processing space 10s. Therefore, the RF power source 31 can function as at least a part of the plasma generator 12. Furthermore, a bias potential is generated in the substrate W by supplying the bias RF signal to at least one lower electrode. Ion components in the formed plasma can be drawn into the substrate W.

In the embodiment, the RF power source 31 includes a first RF generator 31a and a second RF generator 31b. The first RF generator 31a is coupled to at least one lower electrode and/or at least one upper electrode via at least one impedance matching circuit to generate a source RF signal (source RF power) for generating plasma. In the embodiment, the source RF signal has a frequency in a range of 10 to 150 MHz. In the embodiment, the first RF generator 31a may generate a plurality of source RF signals having different frequencies. One or a plurality of generated source RF signals is supplied to at least one lower electrode and/or at least one upper electrode. Note that the first RF generator 31a is an example of the RF generator.

The second RF generator 31b is coupled to at least one lower electrode via at least one impedance matching circuit, and generates a bias RF signal (bias RF power). The bias RF signal may have a frequency the same as or different from that of the source RF signal. In the embodiment, the bias RF signal has a frequency lower than that of the source RF signal. In the embodiment, the bias RF signal has a frequency in a range of 100 kHz to 60 MHz. In the embodiment, the second RF generator 31b may generate a plurality of bias RF signals having different frequencies. One or a plurality of generated bias RF signals is supplied to at least one lower electrode. Furthermore, in various embodiments, at least one of the source RF signal and the bias RF signal may be pulsed.

Furthermore, the power source 30 may include the DC power source 32 coupled to the plasma processing chamber 10. The DC power source 32 includes a first DC generator 32a and a second DC generator 32b. In the embodiment, the first DC generator 32a is connected to at least one lower electrode, and generates a first DC signal. The generated first DC signal is applied to at least one lower electrode. In the embodiment, the second DC generator 32b is connected to at least one upper electrode, and generates a second DC signal. The generated second DC signal is applied to at least one upper electrode.

In various embodiments, the first and second DC signals may be pulsed. In this case, a sequence of voltage pulses is applied to at least one lower electrode and/or at least one upper electrode. The voltage pulses may have a pulse waveform of a rectangle, a trapezoid, a triangle, or a combination thereof. In the embodiment, a waveform generator is connected between the first DC generator 32a and at least one lower electrode. The waveform generator generates a sequence of voltage pulses from a DC signal. Therefore, the first DC generator 32a and the waveform generator constitute a voltage pulse generator. Note that the first DC generator 32a and the waveform generator are examples of a pulsed voltage generator. Furthermore, in the following description, the first DC generator 32a may include the waveform generator. When the second DC generator 32b and the waveform generator constitute the voltage pulse generator, the voltage pulse generator is connected to at least one upper electrode. The voltage pulses may have a positive polarity or a negative polarity. Furthermore, the sequence of voltage pulses may include one or a plurality of positive polarity voltage pulses and one or a plurality of negative polarity voltage pulses in one cycle. Note that the first and second DC generators 32a and 32b may be provided in addition to the RF power source 31. The first DC generator 32a may be provided instead of the second RF generator 31b.

The microwave interferometer 35 measures (monitors) an electron density Ne of plasma generated in the plasma processing space 10s. The microwave interferometer 35 includes electromagnetic horns 36a and 36b. The electromagnetic horns 36a and 36b are attached at two locations of the side wall 10a of the plasma processing chamber 10 so as to face each other. One of the electromagnetic horns 36a and 36b transmits a microwave, and the other receives the microwave. In the plasma processing space 10s, a line connecting the electromagnetic horn 36a with the electromagnetic horn 36b traverses plasma. The microwave interferometer 35 measures the electron density Ne of the plasma based on the phase difference between the transmitted microwave and the received microwave. The microwave interferometer 35 outputs the measured electron density Ne to the controller 2. Note that the controller 2 controls the RF power source 31 (first RF generator 31a) based on the input electron density Ne to adjust a first power level of a first period T1 to be described later for the source RF signal (source RF power). Furthermore, the controller 2 controls the DC power source 32 (first DC generator 32a and waveform generator) based on the input electron density Ne to adjust an offset period De to be described later for the first DC signal (DC pulse). Moreover, the controller 2 may control the DC power source 32 (first DC generator 32a and waveform generator) based on the input electron density Ne to adjust a first voltage level of a second period T2 to be described later for the first DC signal.

The exhaust system 40 can be connected to, for example, a gas discharge port 10e provided in the bottom portion of the plasma processing chamber 10. The exhaust system 40 may include a pressure regulating valve and a vacuum pump. Pressure in the plasma processing space 10s is regulated by the pressure regulating valve. The vacuum pump may include a turbo-molecular pump, a dry pump, or a combination thereof.

### RF Power and DC Pulse

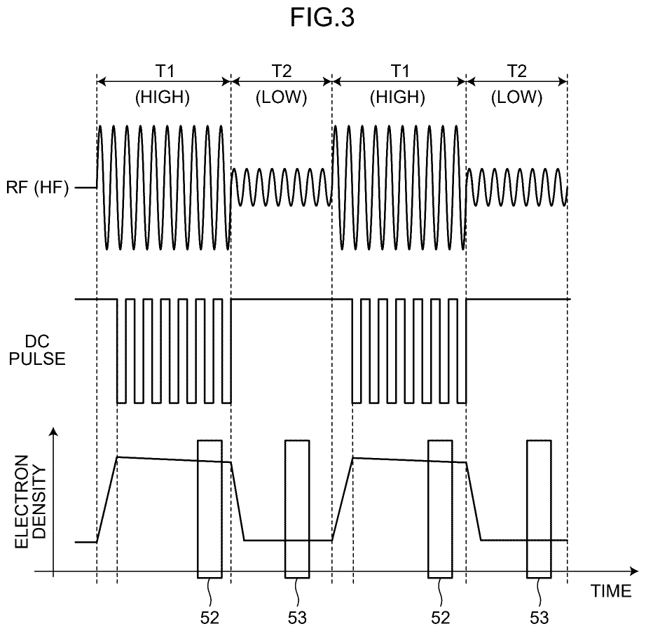

Here, changes in the RF power, the first DC signal (DC pulse), and the electron density Ne will be described. Note that the RF power may have two types of frequencies. The source RF signal having a high frequency is also referred to as a high frequency (HF). The bias RF signal having a low frequency is also referred to as a low frequency (LF). In the embodiment, the relation between the HF, (hereinafter, also referred to as RF (HF)), the DC pulse, and the electron density Ne will be described. FIG. 3 is a timing chart illustrating an example of supply timing of the RF power and the DC pulse and a change in the electron density in the first embodiment.

As illustrated in FIG. 3, the RF power (RF (HF)) and the DC pulse are cyclically supplied with the first period T1 and the second period T2 as one cycle. The RF power is supplied at the first power level (High) in the first period T1, and is supplied at a second power level (Low) in the second period T2. The DC pulse is supplied at a reference voltage level in an offset period (delay period) De to be described later in the first period T1. Furthermore, the DC pulse is supplied as a sequence of a plurality of voltage pulses having the first voltage level after the elapse of the offset period De, that is, in the first period T1 excluding the offset period De. Moreover, the DC pulse is supplied at the reference voltage level in the second period T2. Note that, in FIG. 3, for example, the reference voltage level is 0 V, and the pulse has a negative polarity at the first voltage level.

The electron density Ne increases from the start point of the first period T1, peaks when the supply of the DC pulse is started after the elapse of the offset period De, and is maintained at a first level although electron density Ne tends to slightly decrease. Thereafter, the electron density Ne is reduced from the end point of the first period T1, that is, the start point of the second period T2, decreases to a second level lower than the first level, and is maintained at the second level. In the first embodiment, for example, at timing 52 in the first period T1, the microwave interferometer 35 measures the electron density Ne. The measured electron density Ne is used to subsequently adjust the first power level of an RF (HF). Note that, at timing 53 in the second period T2, the microwave interferometer 35 may measure the electron density Ne.

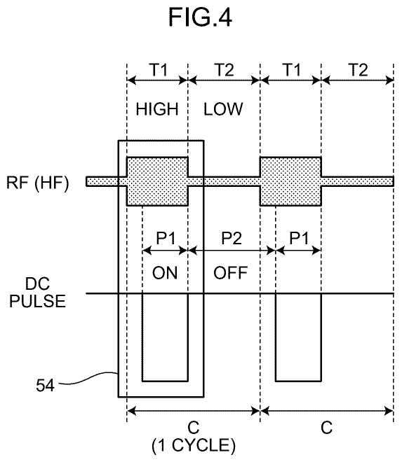

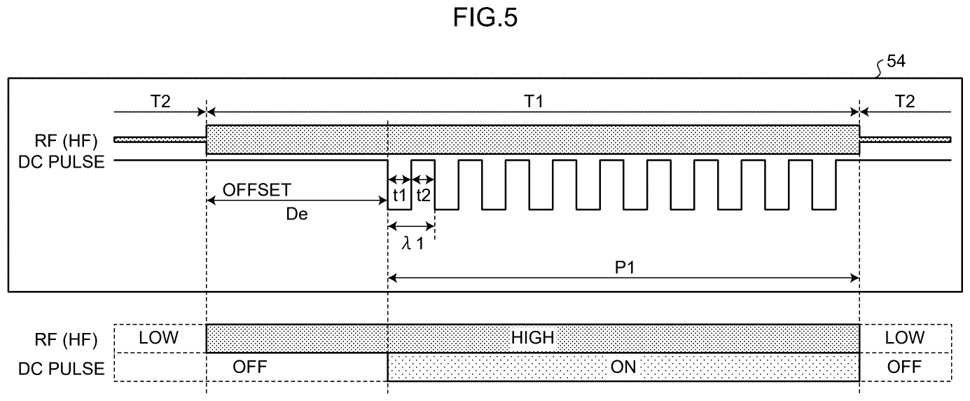

Next, details of the RF power and the DC pulse will be described with reference to FIGS. 4 and 5. FIG. 4 is a timing chart illustrating an example of the supply timing of the RF power and the DC pulse in the first embodiment. FIG. 5 is a timing chart obtained by enlarging a part of the timing chart of FIG. 4. FIG. 5 is obtained by enlarging a range 54 of the timing chart of FIG. 4. As illustrated in FIG. 4, in a process of etching a film to be etched on the substrate W, the RF power (HF) is supplied, and the film to be etched on the substrate W is etched by using plasma generated from processing gas. The RF power source 31 cyclically supplies RF power at the “High” and “Low” levels to the substrate support unit 11 (lower electrode) with a repetition period C in FIG. 4 as one cycle. Note that the RF power may be supplied to the shower head 13 (upper electrode). In the present disclosure, the RF power source 31 (first RF generator 31a) is coupled to the lower electrode, and supplies the RF (HF) in FIG. 4 serving as the RF power.

In FIG. 4, “High” (hereinafter, also referred to as “High state” or “high”) is an example illustrating the first power level of the RF power. For example, the first power level is larger than 0 W. In contrast, “Low” (hereinafter, also referred to as “Low state” or “low”) is an example illustrating the second power level of the RF power. The second power level of the RF power is smaller than the first power level, and is 0 W or larger than 0 W.

The first period T1 when the RF power is put into the High state and the second period T2 when the RF power is put into the Low state are repeated in this order. Note that the first period T1 when the RF power is put into an ON state and the second period T2 when the RF power is put into an OFF state may be repeated in this order. Here, in the ON state, the first power level is similar to that in the High state. In the OFF state, the second power level is 0 W. The first period T1 has a duty ratio in a range of 10 to 60% to the repetition period C. The duty ratio indicates a ratio of the first period T1, and is a ratio of the first period T1 to a total time indicated by (first period T1+second period T2). The repetition period C has a repetition frequency in a range of 0.1 to 50 kHz.

In supply of the DC pulse in FIG. 5, a voltage of a pulse waveform having periodicity and negative polarity is supplied. The “periodicity” here has two meanings. One is periodicity of an ON state in a period P1 in FIG. 4 and an OFF state in a period P2 in FIG. 4. That is, the periodicity corresponds to ON and OFF of a control signal representing whether or not to supply the DC pulse. The period P1 when the ON state is maintained is the first period T1 excluding the offset period De in FIG. 5. The period P2 when the OFF state is maintained is the offset period De and the second period T2. The other is periodicity of ON and OFF of a pulse waveform having a negative polarity in FIG. 5 in the first period T1 (period P1) excluding the offset period De.

The DC power source 32 sets a period when the RF power is in the High state as the first period T1, sets a period when the RF power is in the Low state as the second period T2, and puts the DC pulse into the OFF state in a period from the start of the first period T1 to the end of the offset period De. The offset period De falls within a range of 2 to 7% of the repetition period C. The DC power source 32 puts the DC pulse into the ON state and supplies the DC pulse in the first period T1 after the elapse of the offset period De, that is, the period P1 (=T1−De), and puts the DC pulse into the OFF state in the second period T2. As described above, the DC power source 32 repeats the period P1 when the DC pulse having a negative polarity is supplied and the period P2 (=De+T2) when supply of the DC pulse having a negative polarity is stopped in this order.

In the period P1 when the DC pulse is put into the ON state, the DC pulse further repeats cyclically ON (negative value) and OFF (0 V) as a sequence (pulse waveform) of voltage pulses. That is, the first voltage level has an absolute value larger than that of the reference voltage level. In the period P2, the DC pulse is in the OFF state. That is, a control signal representing whether or not to supply the DC pulse is in the OFF state. Note that, in the period P2, a DC pulse having a smaller absolute value of a voltage than the DC pulse in the period P1 may be supplied.

When a reciprocal of a cycle (wavelength λ1) of ON and OFF of a pulse waveform is set as a pulse frequency f1 in the pulse waveform of the DC pulse in the period P1, the pulse frequency f1 can fall within a range of, for example, 100 kHz to 1 MHz. Furthermore, the duty ratio in the pulse waveform of the DC pulse in the period P1 indicates a ratio of an ON time (t1) of the DC pulse. That is, the duty ratio in the pulse waveform of the DC pulse in the period P1 is a ratio (t1/(t1+t2)) of the ON time to a total time of the ON time (t1) and an OFF time (t2). Note that the DC pulse is not limited to having a rectangular wave. The DC pulse may have a pulse waveform of a triangular wave, an impulse waveform, a trapezoidal wave, a sawtooth wave, or a combination thereof.

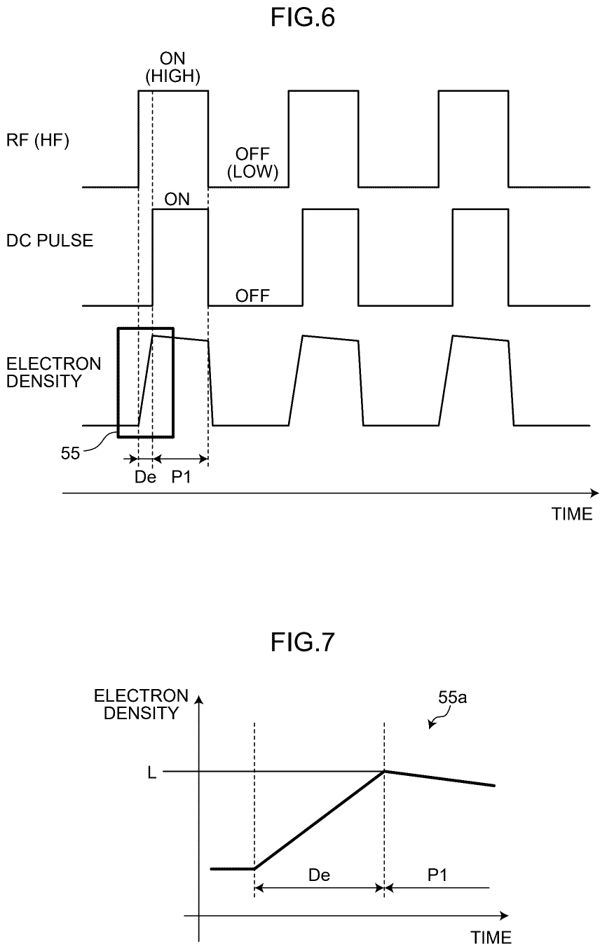

Subsequently, improvement of a mask selection ratio caused by providing an offset period and adjustment of an electron density will be described with reference to FIGS. 6 to 14. FIG. 6 is a timing chart illustrating an example of the supply timing of the RF power and the DC pulse and the change in the electron density in the first embodiment. FIG. 6 corresponds to the timing chart of FIG. 3, and is a timing chart represented by using control signals of the RF power and the DC pulse. As illustrated in FIG. 6, at the rise of the control signals, the control signal of the RF power (RF (HF)) is turned “ON”. After the elapse of the offset period De, the control signal of the DC pulse is turned “ON”. After the elapse of the period P1, at the fall of the control signals, the control signals of the RF (HF) and the DC pulse are simultaneously turned “OFF”. Note that the RF (HF) is supplied at the first power level “High” in a case of “ON”, and is supplied at the second power level “Low” in a case of “OFF”.

Here, in the timing chart of the electron density Ne, a by-product (hereinafter, referred to as deposition) is deposited on the substrate W in the offset period De. The period P1 is an etching period. That is, the deposition deposited on the substrate W in the offset period De protects a mask on the substrate W in the etching in the period P1. That is, it is considered that the mask selection ratio is maximized when an appropriate amount of deposition is deposited. Thus, attention will be paid to the offset period De and a range 55 in the first half of the period P1 of the timing chart of the electron density Ne related to an amount of deposition.

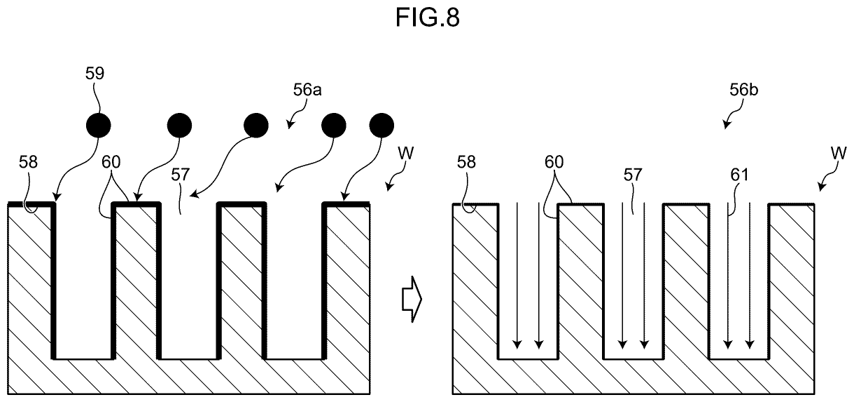

FIG. 7 illustrates an example of a change in electron density near the offset period in a case where an amount of deposition is at an appropriate level. FIG. 8 schematically illustrates deposition and etching in the case where an amount of deposition is at an appropriate level. When the electron density Ne is at an appropriate level L at the start timing of the period P1 as indicated in a range 55a in FIG. 7, deposition 59 is deposited on a side wall of a hole 57 and a surface 58 of the substrate W to form a protective film 60 having an appropriate thickness as indicated in a state 56a in FIG. 8. In the period P1, as indicated in a state 56b in FIG. 8, an ion 61 is drawn, and the bottom portion of the hole 57 is etched. The side wall of the hole 57 and the surface 58 of the substrate W are protected by the protective film 60, and are not etched. That is, since an amount of deposition estimated from the measured electron density Ne is at an appropriate level, the mask selection ratio can be improved.

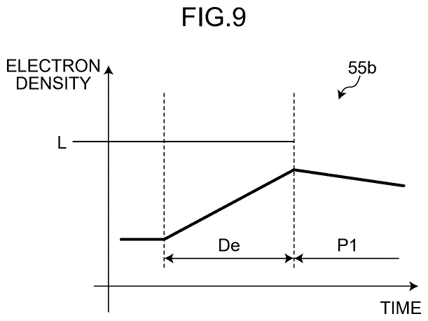

FIG. 9 illustrates an example of a change in electron density near the offset period in a case where an amount of deposition is insufficient. FIG. 10 schematically illustrates deposition and etching in the case where an amount of deposition is insufficient. When the electron density Ne is at a level lower than the appropriate level L at the start timing of the period P1 as indicated in a range 55b in FIG. 9, the deposition 63 is deposited in a smaller amount on the side wall of the hole 57 and the surface 58 of the substrate W to form a protective film 64 thinner than the protective film 60 as indicated in a state 62a in FIG. 10. In the period P1, as indicated in a state 62b in FIG. 10, an ion 65 is drawn, and the bottom portion of the hole 57 is etched. The side wall of the hole 57 and the surface 58 of the substrate W are also etched since the protective film 64 is thin. The mask selection ratio thus decreases. When the electron density Ne is at a level lower than the appropriate level L at the start timing of the period P1 as indicated in the range 55b, the RF power source 31 (first RF generator 31a) is controlled to increase the first power level of the RF (HF). Note that the appropriate level L is an example of a target value of the electron density Ne.

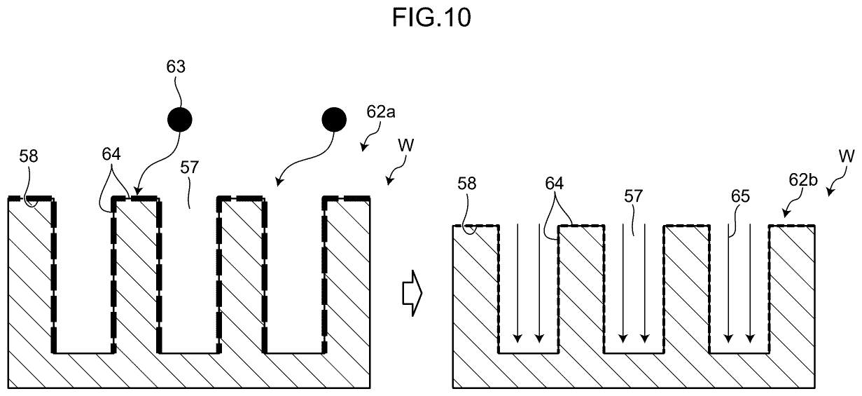

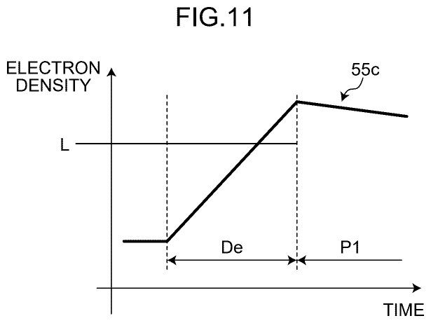

FIG. 11 illustrates an example of a change in electron density near the offset period in a case where an amount of deposition is excessive. FIG. 12 schematically illustrates deposition and etching in the case where an amount of deposition is excessive. When the electron density Ne is at a level higher than the appropriate level L at the start timing of the period P1 as indicated in a range 55c in FIG. 11, a large amount of deposition 67 is deposited as indicated in a state 66a in FIG. 12. In this case, not only the deposition 67 is deposited on the side wall of the hole 57 and the surface 58 of the substrate W but a formed protective film 68 is etched by the deposition 67 to be thinner than the protective film 60. In the period P1, as indicated in a state 66b in FIG. 12, an ion 69 is drawn, and the bottom portion of the hole 57 is etched. The side wall of the hole 57 and the surface 58 of the substrate W are also etched since the protective film 68 is thin. The mask selection ratio thus decreases. When the electron density Ne is at a level higher than the appropriate level L at the start timing of the period P1 as indicated in the range 55c, the RF power source 31 (first RF generator 31a) is controlled to decrease the first power level of the RF (HF).

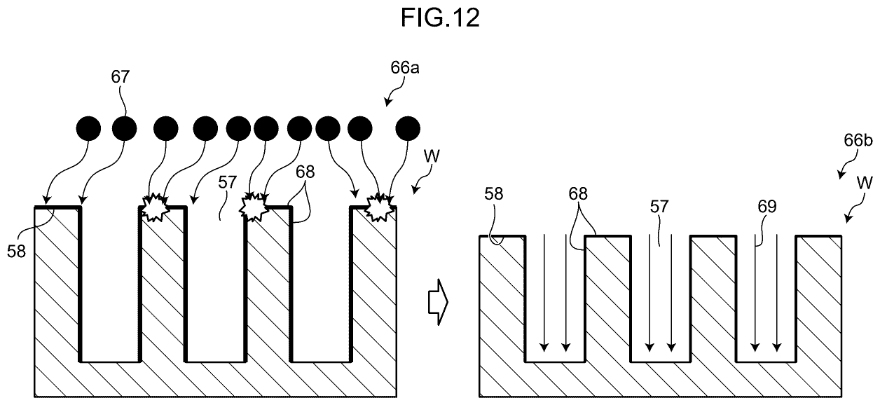

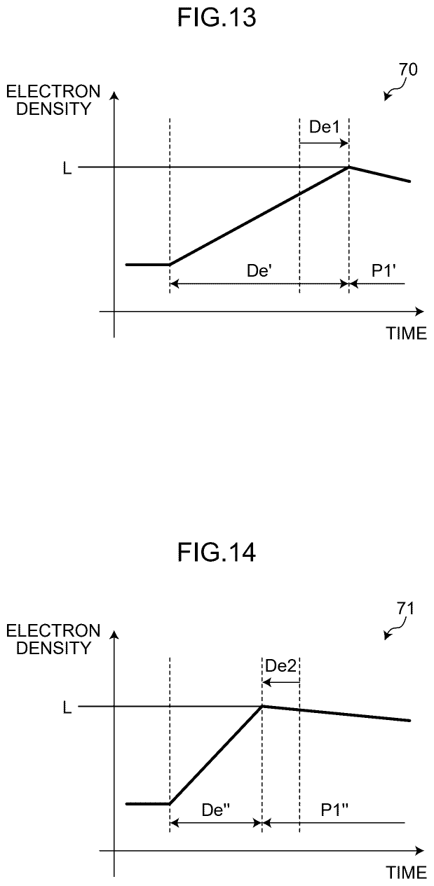

Furthermore, the electron density Ne may be adjusted by the length of the offset period De. FIG. 13 illustrates an example of a method of adjusting the electron density at the start timing of the period P1. A range 70 in FIG. 13 corresponds to the range 55 in FIG. 6. FIG. 13 illustrates an adjustment example in a case where the electron density Ne at the start timing of the period P1 is insufficient as compared to that at the appropriate level L as indicated in the range 55b in FIG. 9. In an example of the range 70, an adjustment is made such that an addition period De1 is added to the offset period De to form an offset period De′. Note that the relation of first period T1=offset period De+period P1 holds. When the range 70 is adjusted, period P1′=period P1-addition period De1 holds, and first period T1=offset period De′+period P1′ holds. When the electron density Ne at the start timing of the period P1 is insufficient as compared to that at the appropriate level L as described above, the DC power source 32 (first DC generator 32a and waveform generator) may be controlled to extend the offset period De.

FIG. 14 illustrates an example of the method of adjusting the electron density at the start timing of the period P1. A range 71 in FIG. 14 corresponds to the range 55 in FIG. 6. FIG. 14 illustrates an adjustment example in a case where the electron density Ne at the start timing of the period P1 is excessive as compared to that at the appropriate level L as indicated in the range 55c in FIG. 11. In an example of the range 71, an adjustment is made such that a shortened period De2 is reduced from the offset period De to form an offset period De″. Note that the relation of first period T1=offset period De+period P1 holds. When the range 71 is adjusted, period P1″=period P1+shortened period De2 holds, and first period T1=offset period De″+period P1″ holds. When the electron density Ne at the start timing of the period P1 is excessive as compared to that at the appropriate level L as described above, the DC power source 32 (first DC generator 32a and waveform generator) may be controlled to shorten the offset period De. Note that adjustment of the first power level of the RF (HF) and adjustment of the offset period De may be combined.

### Plasma Control Method

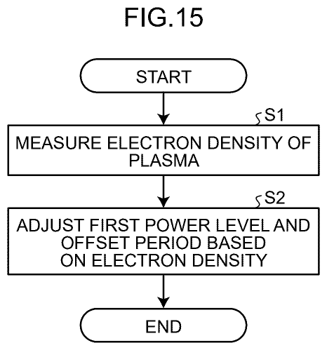

Subsequently, an example of plasma control processing in the plasma processing apparatus 1 of the first embodiment will be described. FIG. 15 is a flowchart illustrating an example of the plasma control processing according to the first embodiment. The plasma control processing in FIG. 15 is performed by the controller 2 controlling units of the plasma processing apparatus 1.

First, the substrate W is carried into the plasma processing chamber 10, and is supported on the substrate support unit 11. Then, the controller 2 controls the gas supply unit 20 so that a predetermined flow volume of processing gas is supplied into the plasma processing chamber 10. Then, the controller 2 controls the exhaust system 40 to adjust pressure in the plasma processing chamber 10. Next, the controller 2 controls the RF power source 31 and the DC power source 32 to supply the RF power and the DC pulse to the substrate support unit 11, which is a lower electrode. This generates plasma of the processing gas in the plasma processing chamber 10. The controller 2 controls the microwave interferometer 35 to measure the electron density Ne of the plasma (Step S1). The microwave interferometer 35 outputs the measured electron density Ne to the controller 2. Note that the microwave interferometer 35 continuously measures the electron density Ne of the plasma in plasma processing at the time of adjustment.

When the measured electron density Ne is input from the microwave interferometer 35, the controller 2 controls the RF power source 31 and the DC power source 32 to adjust at least one of the first power level and the offset period De based on the input electron density Ne (Step S2). That is, the controller 2 controls the RF power source 31 and the DC power source 32 to adjust at least one of the first power level and the offset period De and set the input electron density Ne to the appropriate level L.

When a plasma processing process ends, a robot arm (not illustrated) carries the processed substrate W out of the plasma processing chamber 10.

As described above, in the first embodiment, at least one of the first power level and the offset period De is adjusted based on the measured electron density Ne, so that a temporal change in a plasma condition can be inhibited.

### Second Embodiment

Although, in the above-described first embodiment, the DC pulse is supplied at the time when the RF power is in the High state, the DC pulse may be supplied at the time when the RF power is in the Low state. An embodiment in this case will be described as a second embodiment. Note that a plasma processing system in the second embodiment is similar to that of the above-described first embodiment except for the supply timing of the DC pulse, and thus descriptions of the overlapping configuration and operation will be omitted.

Furthermore, in the above-described first embodiment, at least one of the first power level of the first period T1 and the offset period De is adjusted based on the electron density Ne measured in the first period T1. In contrast, in the second embodiment, for example, the first power level of the RF power is adjusted based on the electron density Ne measured in the first period T1, and the first voltage level of the DC pulse is adjusted based on the electron density Ne measured in the second period T2.

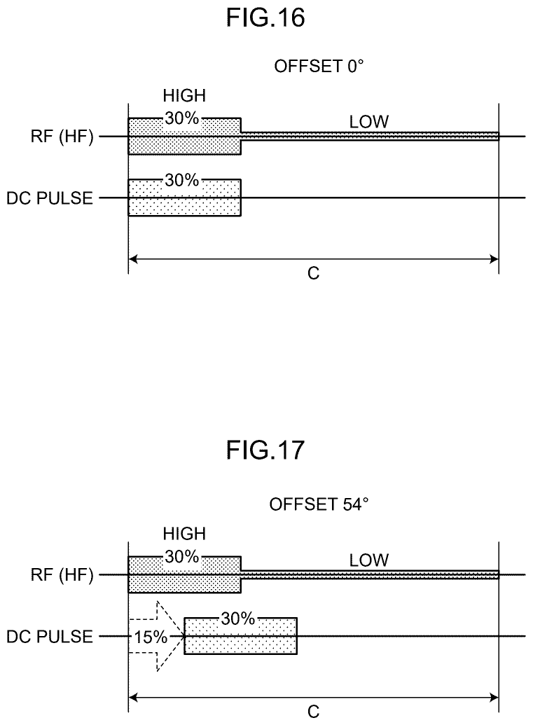

First, a synchro pulse and a timing offset pulse (hereinafter, also referred to as offset pulse) will be described with reference to FIGS. 16 to 19. FIG. 16 illustrates an example of a timing chart for one cycle of a synchro pulse. As illustrated in FIG. 16, the synchro pulse is provided in a case where the DC pulse has an offset of 0° to the RF power (RF (HF)). Furthermore, in an example of FIG. 16, duty ratios of the RF (HF) and the DC pulse to the repetition period C are 30%. That is, the RF (HF) and the DC pulse are simultaneously supplied to the lower electrode (substrate support unit 11) of the plasma processing chamber 10. Note that the phase of an offset is represented in degrees (angles).

FIGS. 17 to 19 illustrate examples of a timing chart for one cycle of an offset pulse. FIG. 17 illustrates a case where the DC pulse has an offset of 54° with respect to the RF (HF). That is, the phase of the DC pulse in FIG. 17 is delayed by 15% with respect to a synchro pulse. In an example of FIG. 17, duty ratios of the RF (HF) and the DC pulse are 30%. That is, after supply of the RF (HF) to the lower electrode (substrate support unit 11) of the plasma processing chamber 10 is started and 15% of the repetition period C elapses, supply of the DC pulse to the lower electrode (substrate support unit 11) of the plasma processing chamber 10 is started. That is, in the repetition period C, a High state of the RF (HF) and an OFF state of the DC pulse, a High state of the RF (HF) and an ON state of the DC pulse, a Low state of the RF (HF) and an ON state of the DC pulse, and a Low state of the RF (HF) and an OFF state of the DC pulse come in the order.

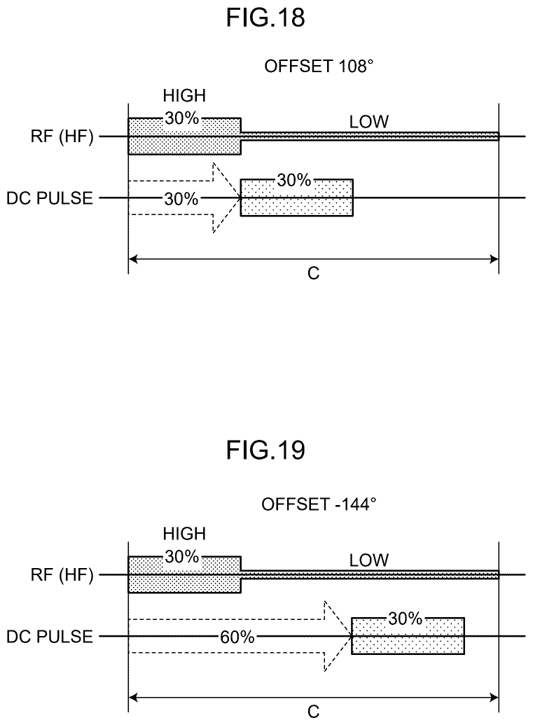

FIG. 18 illustrates a case where the DC pulse has an offset of 108° with respect to the RF (HF). That is, the phase of the DC pulse in FIG. 18 is delayed by 30% with respect to a synchro pulse. In an example of FIG. 18, duty ratios of the RF (HF) and the DC pulse are 30%. That is, after supply of the RF (HF) to the lower electrode (substrate support unit 11) of the plasma processing chamber 10 is started and 30% of the repetition period C elapses, supply of the DC pulse to the lower electrode (substrate support unit 11) of the plasma processing chamber 10 is started. That is, in the repetition period C, a High state of the RF (HF) and an OFF state of the DC pulse, a Low state of the RF (HF) and an ON state of the DC pulse, and a Low state of the RF (HF) and an OFF state of the DC pulse come in the order.

FIG. 19 illustrates a case where the DC pulse has an offset of −144° with respect to the RF (HF). That is, the phase of the DC pulse in FIG. 19 is advanced by 40% (delayed by 60%) with respect to a synchro pulse. In an example of FIG. 19, duty ratios of the RF (HF) and the DC pulse are 30%. That is, after supply of the RF (HF) to the lower electrode (substrate support unit 11) of the plasma processing chamber 10 is started and 60% of the repetition period C elapses, supply of the DC pulse to the lower electrode (substrate support unit 11) of the plasma processing chamber 10 is started. That is, in the repetition period C, a High state of the RF (HF) and an OFF state of the DC pulse, a Low state of the RF (HF) and an OFF state of the DC pulse, a Low state of the RF (HF) and an ON state of the DC pulse, and a Low state of the RF (HF) and an OFF state of the DC pulse come in the order.

For the synchro pulses and the offset pulses in FIGS. 16 to 19, a period when the RF (HF) is in the High state is set as the first period T1, and a period when the RF (HF) is in a Low state is set as the second period T2. In the second embodiment, the first power level at which the RF (HF) is in the High state is adjusted based on the electron density Ne of plasma measured in the first period T1. Furthermore, in the second embodiment, the first voltage level at which the DC pulse is in the ON state is adjusted based on the electron density Ne of plasma measured in the second period T2.

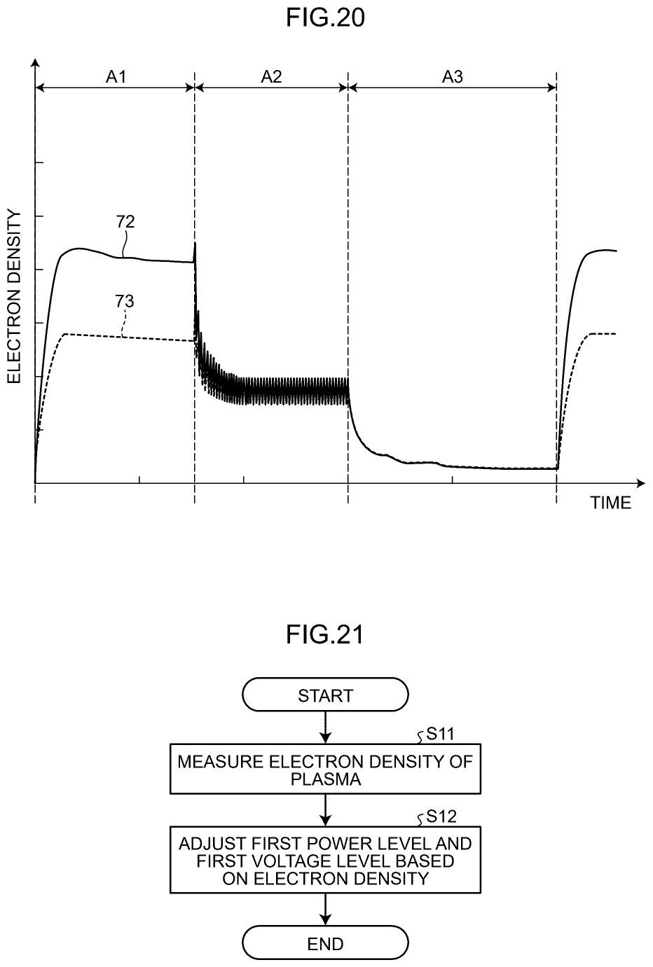

Next, an adjustment example in an offset pulse will be described with reference to FIG. 20. FIG. 20 is a graph illustrating an example of a change in electron density in a repetition period in the second embodiment. FIG. 20 illustrates a change in the electron density Ne in a case where the offset in FIG. 18 is 108°. That is, FIG. 20 illustrates a change in the electron density Ne in a period A1, a period A2, and a period A3 for the repetition period C. The period A1 corresponds to the first period T1. The period A2 corresponds to a period when the DC pulse is in the ON state of the second period T2. The period A3 corresponds to a period when the DC pulse is in the OFF state of the second period T2. That is, in the period A1, the RF (HF) is in the High state, and the DC pulse is in the OFF state. In the period A2, the RF (HF) is in the Low state, and the DC pulse is in the ON state. In the period A3, the RF (HF) is in the Low state, and the DC pulse is in the OFF state. For example, a graph 72 of FIG. 20 is an example of a change in the electron density Ne in the plasma condition immediately after maintenance. In the graph 72, the electron density Ne in the period A1 increases to approximately twice the electron density Ne in the period A2.

In this case, the controller 2 controls the RF power source 31 so that the electron density Ne is constant at a target value for the first power level at which the RF (HF) is in the High state in the period A1. Furthermore, the controller 2 controls the DC power source 32 so that the electron density Ne is constant at a target value for the first voltage level at which the DC pulse is in the ON state in the period A2. Furthermore, the controller 2 controls the RF power source 31 so that plasma is maintained for the second power level at which the RF (HF) is in the Low state in the period A3. Note that, in the periods A1 and A2, it is considered that the first power level of the RF (HF) and the first voltage level of the DC pulse may influence each other. In this case, in the periods A1 and A2, each of the first power level of the RF (HF) and the first voltage level of the DC pulse may be adjusted. That is, the electron density Ne may be controlled so as to be constant at a target value in each of the periods A1 and A2 by the balance between the first power level of the RF (HF) and the first voltage level of the DC pulse. Note that the control method can be applied not only to an offset pulse but to a synchro pulse.

A graph 73 of FIG. 20 illustrates an example of a change in the electron density Ne in the plasma condition in a case where time has elapsed from maintenance and plasma processing has been performed for a long time in the plasma processing chamber 10. When the graph 73 is compared with the graph 72, the electron density Ne in the period A1 of the graph 73 is lower than that of the graph 72 corresponding to a target value. In this case, the controller 2 controls the RF power source 31 to increase the first power level of the RF (HF) in the period A1 so that the electron density Ne in the period A1 reaches the target value (overlaps graph 72).

That is, when the electron density Ne is less than the target value in the first period T1 (period A1), the controller 2 controls the RF power source 31 to increase the first power level of the RF (HF). Furthermore, when the electron density Ne exceeds the target value in the first period T1 (period A1), the controller 2 controls the RF power source 31 to decrease the first power level of the RF (HF). Similarly, when the electron density Ne is less than the target value in the second period T2 (e.g., period A2), the controller 2 controls the DC power source 32 to increase the first voltage level of the DC pulse. Furthermore, when the electron density Ne exceeds the target value in the second period T2 (e.g., period A2), the controller 2 controls the DC power source 32 to decrease the first voltage level of the DC pulse.

### Plasma Control Method

Subsequently, an example of plasma control processing in the plasma processing apparatus 1 of the second embodiment will be described. FIG. 21 is a flowchart illustrating an example of the plasma control processing according to the second embodiment. The plasma control processing in FIG. 21 is performed by the controller 2 controlling units of the plasma processing apparatus 1.

First, the substrate W is carried into the plasma processing chamber 10, and is supported on the substrate support unit 11. Then, the controller 2 controls the gas supply unit 20 so that a predetermined flow volume of processing gas is supplied into the plasma processing chamber 10. Then, the controller 2 controls the exhaust system 40 to adjust pressure in the plasma processing chamber 10. Next, the controller 2 controls the RF power source 31 and the DC power source 32 to supply the RF power and the DC pulse to the substrate support unit 11, which is a lower electrode. This generates plasma of the processing gas in the plasma processing chamber 10. The controller 2 controls the microwave interferometer 35 to measure the electron density Ne of the plasma (Step S11). The microwave interferometer 35 outputs the measured electron density Ne to the controller 2. Note that the microwave interferometer 35 continuously measures the electron density Ne of the plasma in plasma processing at the time of adjustment.

When measured electron densities Ne are input from the microwave interferometer 35, the controller 2 controls the RF power source 31 to adjust the first power level based on an electron density Ne measured in the first period T1 among the input electron densities Ne. Furthermore, the controller 2 controls the DC power source 32 to adjust the first voltage level based on an electron density Ne measured in the second period T2 among the input electron densities Ne (Step S12). That is, the controller 2 adjusts the first power level and the first voltage level, and controls the RF power source 31 and the DC power source 32 so that the input electron densities Ne reach target values of the first period T1 and the second period T2.

When a plasma processing process ends, a robot arm (not illustrated) carries the processed substrate W out of the plasma processing chamber 10.

As described above, in the second embodiment, the first power level and the first voltage level are adjusted based on the electron densities Ne measured in the first period T1 and the second period T2, so that a temporal change in a plasma condition can be inhibited.

As described above, according to the second embodiment, the plasma processing apparatus 1 includes the chamber (plasma processing chamber 10), the substrate support unit 11 disposed in the chamber and including the lower electrode, the RF generator (RF power source 31), the pulsed voltage generator (DC power source 32), the microwave interferometer 35, and the controller 2. The RF generator generates a pulsed RF signal to generate plasma in the chamber. The pulsed RF signal has the first power level in the first period T1 in each cycle (repetition period C), and has the second power level smaller than the first power level in the second period T2 in each cycle. The pulsed voltage generator is electrically connected to the lower electrode, and generates a pulsed voltage signal. The pulsed voltage signal has the reference voltage level in the first period T1, and has a sequence of a plurality of voltage pulses having the first voltage level in the second period T2. The first voltage level has an absolute value larger than that of the reference voltage level. The microwave interferometer 35 monitors the electron density of plasma in the chamber. The controller 2 adjusts the first power level based on the electron density of plasma monitored in the first period T1, and adjusts the first voltage level based on the electron density of plasma monitored in the second period T2. As a result, a temporal change in a plasma condition can be inhibited.

Furthermore, according to the second embodiment, when the electron density in the first period T1 is less than a target value, the controller 2 makes an adjustment to increase the first power level. As a result, the electron density in the first period T1 can be adjusted.

Furthermore, according to the second embodiment, when the electron density in the first period T1 exceeds the target value, the controller 2 makes an adjustment to decrease the first power level. As a result, the electron density in the first period T1 can be adjusted.

Furthermore, according to the second embodiment, when the electron density in the second period T2 is less than a target value, the controller 2 makes an adjustment to increase the absolute value of the first voltage level. As a result, the electron density in the second period T2 can be adjusted.

Furthermore, according to the second embodiment, when the electron density in the second period T2 exceeds the target value, the controller 2 makes an adjustment to decrease the absolute value of the first voltage level. As a result, the electron density in the second period T2 can be adjusted.

Furthermore, according to the first embodiment, the plasma processing apparatus 1 includes the chamber (plasma processing chamber 10), the substrate support unit 11 disposed in the chamber and including the lower electrode, the RF generator (RF power source 31), the pulsed voltage generator (DC power source 32), the microwave interferometer 35, and the controller 2. The RF generator generates a pulsed RF signal to generate plasma in the chamber. The pulsed RF signal has the first power level in the first period T1 in each cycle (repetition period C), and has the second power level smaller than the first power level in the second period T2 in each cycle. The pulsed voltage generator is electrically connected to the lower electrode, and generates a pulsed voltage signal. The pulsed voltage signal has the reference voltage level in the delay period (offset period De) in the first period T1, has a sequence of a plurality of voltage pulses having the first voltage level in the first period T1 excluding the delay period, and has the reference voltage level in the second period T2. The first voltage level has an absolute value larger than that of the reference voltage level. The delay period falls within a range of 2 to 7% of a total period of each cycle. The microwave interferometer 35 monitors the electron density of plasma in the chamber. The controller 2 adjusts at least one of the first power level and the delay period based on the electron density of plasma monitored in the delay period. As a result, a temporal change in a plasma condition can be inhibited.

Furthermore, according to the first embodiment, when the electron density is less than a target value, the controller 2 makes an adjustment to increase the first power level or extend the delay period. As a result, the electron density in the first period T1 can be adjusted.

Furthermore, according to the first embodiment, when the electron density exceeds the target value, the controller 2 makes an adjustment to decrease the first power level or shorten the delay period. As a result, the electron density in the first period T1 can be adjusted.

It should be understood that the embodiments disclosed herein are illustrative in all respects and not restrictive. Each of the above-described embodiments may be omitted, replaced, or modified in various forms without departing from the scope and gist of the appended claims.

According to the present disclosure, a temporal change in a plasma condition can be inhibited.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth. The present disclosure encompasses various modifications to each of the examples and embodiments discussed herein. According to the disclosure, one or more features described above in one embodiment or example can be equally applied to another embodiment or example described above. The features of one or more embodiments or examples described above can be combined into each of the embodiments or examples described above. Any full or partial combination of one or more embodiment or examples of the disclosure is also part of the disclosure.

What is claimed is:

1. A plasma processing apparatus comprising:
a chamber;
a substrate support disposed in the chamber and including a lower electrode;
an RF generator that generates a pulsed RF signal in order to generate plasma in the chamber, the pulsed RF signal having a first power level in a first period in each cycle and having a second power level smaller than the first power level in a second period in each cycle;
a pulsed voltage generator that is electrically connected to the lower electrode and that generates a pulsed voltage signal, the pulsed voltage signal having a reference voltage level in the first period and having a sequence of a plurality of voltage pulses having a first voltage level in the second period, the first voltage level having an absolute value larger than an absolute value of the reference voltage level;
a microwave interferometer that monitors an electron density of plasma in the chamber; and
controller circuitry configured to:
control the RF generator to adjust the first power level based on an electron density of plasma monitored in the first period, and
control the pulsed voltage generator to adjust the first voltage level based on an electron density of plasma monitored in the second period.

2. The plasma processing apparatus according to claim 1,
wherein, when the electron density in the first period is less than a target value, the controller circuitry is configured to control the RF generator to increase the first power level.

3. The plasma processing apparatus according to claim 1,
wherein, when the electron density in the first period exceeds a target value, the controller circuitry is configured to control the RF generator to decrease the first power level.

4. The plasma processing apparatus according to claim 1,
wherein, when the electron density in the second period is less than a target value, the controller circuitry is configured to control the pulsed voltage generator to increase an absolute value of the first voltage level.

5. The plasma processing apparatus according to claim 1,
wherein, when the electron density in the second period exceeds a target value, the controller circuitry is configured to control the pulsed voltage generator to decrease an absolute value of the first voltage level.

6. The plasma processing apparatus according to claim 1, wherein the pulsed voltage signal has a phase offset with respect to the pulsed RF signal.

7. The plasma processing apparatus according to claim 1, wherein the first period has a duty ratio in a range of 10 to 60% of a repetition period of each cycle.

8. The plasma processing apparatus according to claim 1, wherein the pulsed RF signal has a repetition frequency in a range of 0.1 to 50 kHz.

9. The plasma processing apparatus according to claim 1, wherein the microwave interferometer includes a pair of electromagnetic horns attached to a side wall of the chamber so as to face each other, and measures the electron density based on a phase difference between a transmitted microwave and a received microwave.

10. The plasma processing apparatus according to claim 9, wherein the controller circuitry is configured to control the RF generator to increase the first power level when the electron density in the first period is less than a target value, and controls the pulsed voltage generator to increase an absolute value of the first voltage level when the electron density in the second period is less than the target value.

11. The plasma processing apparatus according to claim 1, wherein the controller circuitry controls the RF generator to decrease the first power level when the electron density in the first period exceeds a target value, and controls the pulsed voltage generator to decrease an absolute value of the first voltage level when the electron density in the second period exceeds the target value.

12. A plasma processing apparatus comprising:
a chamber;
a substrate support disposed in the chamber and including a lower electrode;
an RF generator that generates a pulsed RF signal in order to generate plasma in the chamber, the pulsed RF signal having a first power level in a first period in each cycle and having a second power level smaller than the first power level in a second period in each cycle;
a pulsed voltage generator that is electrically connected to the lower electrode and that generates a pulsed voltage signal, the pulsed voltage signal having a reference voltage level in a delay period in the first period, having a sequence of a plurality of voltage pulses having a first voltage level in the first period excluding the delay period, and having the reference voltage level in the second period, the first voltage level having an absolute value larger than an absolute value of the reference voltage level, the delay period falling within a range of 2 to 7% of a total period in each cycle;
a microwave interferometer that monitors an electron density of plasma in the chamber; and
controller circuitry configured to control the RF generator to adjust at least one of the first power level and the delay period based on an electron density of plasma monitored in the delay period.

13. The plasma processing apparatus according to claim 12,
wherein, when the electron density is less than a target value, the controller circuitry is configured to adjust the RF generator increase the first power level or extend the delay period.

14. The plasma processing apparatus according to claim 12,
wherein, when the electron density exceeds a target value, the controller circuitry is configured to control the RF generator to decrease the first power level or shorten the delay period.

15. The plasma processing apparatus according to claim 12, wherein the first period has a duty ratio in a range of 10 to 60% of a total period of each cycle.

16. The plasma processing apparatus according to claim 12, wherein the pulsed RF signal has a repetition frequency in a range of 0.1 to 50 kHz.

17. The plasma processing apparatus according to claim 12, wherein a sequence of the plurality of voltage pulses in the first period excluding the delay period has a pulse frequency in a range of 100 kHz to 1 MHz.

18. A plasma control method comprising:
generating plasma in a chamber by supplying a pulsed RF signal to a substrate support disposed in the chamber and including a lower electrode, the pulsed RF signal having a first power level in a first period in each cycle and having a second power level smaller than the first power level in a second period in each cycle;
supplying a pulsed voltage signal to the lower electrode, the pulsed voltage signal having a reference voltage level in a delay period in the first period, having a sequence of a plurality of voltage pulses having a first voltage level in the first period excluding the delay period, and having the reference voltage level in the second period, the first voltage level having an absolute value larger than an absolute value of the reference voltage level, the delay period falling within a range of 2 to 7% of a total period of each cycle;
measuring an electron density of the plasma; and
adjusting at least one of the first power level and the delay period based on the electron density measured in the delay period.

19. The plasma control method according to claim 18, wherein the adjusting includes increasing the first power level or extending the delay period when the electron density is less than a target value.

20. The plasma control method according to claim 18, wherein the adjusting includes decreasing the first power level or shortening the delay period when the electron density exceeds a target value.
